(19) United States
(12) Patent Application Publication
(10) Pub. No.: US 2008/0032103 A1
(43) Pub. Date: Feb. 7, 2008

(54) Multilayer Printed Circuit Board

(75) Inventors: Takashi Kikuchi, Shiga (JP); Hiroyuki Tsuji, Kanagawa (JP); Takashi Itoh, Shiga (JP); Shigeru Tanaka, Osaka (JP); Eiichiro Kuribayashi, Pasadena, TX (US); Greg Clements, Pasadena, TX (US)

Correspondence Address: OSHA LIANG L.L.P., 1221 MCKINNEY STREET, SUITE 2800, HOUSTON, TX, 77010, US

(73) Assignees: KANEKA TEXAS CORPORATION, PASADENA, TX (US); KANEKA CORPORATION, OSAKA (JP)

(21) Appl. No.: 11/587,771

(22) PCT Filed: Apr. 27, 2005
(86) PCT No.: PCT/US05/14360

§ 371 Date: Jun. 27, 2007

Related U.S. Application Data
(60) Provisional application No. 60/565,575, filed on Apr. 27, 2004.

(51) Int. Cl. H05K 1/03; H05K 3/46

(52) U.S. Cl. 428/214; 428/474.4

(57) ABSTRACT

A multilayer printed circuit board can be used in high-frequency applications, is not easily affected by environmental changes, and has stable dielectric characteristics. A multilayer printed circuit board suitable for use in the high-frequency range includes at least two printed wiring sheets laminated with an interlayer bonding member therebetween. At least one of the at least two printed wiring sheets includes an insulating film, an adhesive layer containing a thermoplastic polyimide disposed on at least one surface of the insulating film, and a metal wiring layer disposed on the adhesive layer. The interlayer bonding member contains a thermoplastic polyimide.

### TECHNICAL FIELD

The present invention relates to multilayer printed circuit boards which can be used in high-frequency applications, which are not easily affected by the environment, and which are highly reliable.

### BACKGROUND ART

In order to cope with reductions in the mounting space due to miniaturization of electrical devices and increases in the number of interconnections due to improved functionality, multilayer printed circuit boards have been used in which a plurality of wiring layers are laminated to form three-dimensional wiring structures. Currently, multilayer printed circuit boards having rigid substrates composed of epoxy-impregnated glass cloth or the like are being predominantly used. An example of a rigid substrate is disclosed in Japanese Patent Publication No. 7-162154, titled “Multilayer Printed Wiring Board.” The use of rigid substrates can pose one or more of the following problems.

A first problem relates to the flexibility of the substrate. In general, a rigid substrate is produced by impregnating a fibrous base composed of glass cloth, aramid paper, or the like with a thermosetting resin, such as an epoxy resin or a phenol resin, followed by hardening. Therefore, the rigid substrate has low flexibility. Consequently, it is difficult to fold the substrate so as to be placed in an open space of an electronic device.

A second problem relates to the thickness of the substrate. As described above, a rigid substrate is produced by impregnating a fibrous base composed of glass cloth, aramid paper, or the like with a thermosetting resin. Therefore, the thickness of the substrate is restricted by the fiber thickness of the base, and there is a limitation in decreasing the thickness of the substrate. Furthermore, since the base is impregnated with the thermosetting resin, the dielectric characteristics of the substrate itself are not very good. From the standpoint of securing interlayer insulation, it is not possible to decrease the thickness of the substrate. If a plurality of substrates each having a large thickness are laminated to form a multilayer circuit board, the thickness of the multilayer circuit board will become relatively large.

A third problem relates to surface smoothness. Since the rigid substrate includes a fibrous base, the smoothness of the surface of the substrate is not very good. Consequently, transmission loss increases when a wiring sheet is formed by disposing a metal wiring layer on the substrate.

In view of the problems described above, multilayer printed circuit boards have been developed in which wiring sheets including rigid substrates are partially disposed on a wiring sheet including a substrate composed of an insulating film. Such a printed circuit board is disclosed in Japanese Patent Publication No. 6-268339, titled “Flex-Rigid Multilayer Printed Wiring Board and Production Therof.” Since the multilayer printed circuit board having such a structure has flexible parts, folding can be performed in these parts, and thus the problem of flexibility is overcome. However, since the rigid substrates are still included, the problems of the thickness of the substrate and the surface smoothness are not overcome.

In order to cope with the remaining problems, multilayer printed circuit boards comprising only wiring sheets including substrates each composed of an insulating film have come into use. In such multilayer printed circuit boards, since an insulating film is used for the substrate, interlayer insulation can be more easily ensured compared with the rigid substrate. The thickness of each wiring sheet and the thickness of the entire multilayer board can be decreased. Furthermore, since a highly smooth film is used as the base, the problem of surface smoothness is overcome. Moreover, if a rigid substrate is used, conductive anodic filaments (CAFs) may grow along the glass fiber interfaces between via-holes or between via-holes and patterns, resulting in a decrease in insulating properties. However, when the insulating film is used, since the glass fiber that generates CAFs is not involved, the decrease in insulating properties attributable to CAFs can be avoided.

Meanwhile, recently, in order to improve information processing capability in electronic devices, frequencies of electrical signals transmitted through circuits have been increased. As the frequencies of electrical signals increase, the wiring substrates are required to maintain electrical reliability and prevent decreases in the transmission speed of electrical signals and the loss of electrical signals. Materials having low dielectric constants and low dielectric loss tangents in the high-frequency range (on the order of GHz or more) are desired.

Here, the multilayer printed circuit boards described above will be examined. With respect to the multilayer printed circuit board in which rigid substrates are partially or entirely used, dielectric characteristics of the substrates are generally poor, and it is difficult to exhibit low-dielectric characteristics in the high-frequency range. Furthermore, in the high-frequency range, the influence of transmission loss due to poor surface smoothness is increased. Thus, it is difficult to cope with the increases in frequencies of electrical signals.

In order to fabricate the multilayer printed circuit board including substrates each composed of an insulating film, printed wiring sheets each including an insulating film and a metal wiring layer disposed on the insulating film with an adhesive layer therebetween are laminated using an interlayer bonding member. For example, a copper foil is laminated on a polyimide film using a thermosetting resin, such as an epoxy resin, as an adhesive, and a circuit is formed by etching. As the interlayer bonding member, a thermosetting resin, such as an epoxy or acrylic resin, is usually used. Such a multilayer printed circuit board also has poor dielectric characteristics. Consequently, as the frequencies further increase, specifically, in a range of 10 GHz or more, the dielectric characteristics of the entire multilayer board are believed to be degraded.

On the other hand, a copper-clad laminate which includes no adhesive layer or which includes an adhesive layer composed of a polyimide material has been proposed by several companies. Examples of such laminates are disclosed in Japanese Patent Publication Nos. 3-104185, 5-327207, and 2001-129918, respectively titled, “Manufacture of Double Surface Conductor Polyimide Laminate,” “Manufacture of Polyimide Base Plate,” and “Manufacturing Method of Laminated Sheet.”

With respect to the interlayer bonding member, a method has been proposed in which polyimide varnish is applied to a wiring sheet, followed by drying to form an adhesive layer, and interlayer bonding is performed using the adhesive layer. An example of such a method is disclosed in Japanese Patent Publication No. 5-275568, titled “Multilayer Interconnection Circuit Board and Manufacture Thereof.”

Despite the improvements in multilayer circuit boards, as discussed above, further improvements in performance, manufacturing, and reliability are still achievable. For example, further improvements may include a reduction in dielectric characteristics in the high-frequency range, increased resistance to soldering heat, and increased dimensional stability.

### SUMMARY OF INVENTION

In one aspect, the present invention relates to a multilayer printed circuit board including at least two printed wiring sheets laminated with an interlayer bonding member therebetween. At least one of the printed wiring sheets includes a non-thermoplastic polyimide film, an adhesive layer containing a thermoplastic polyimide disposed on at least one surface of the non-thermoplastic polyimide film, and a metal wiring layer disposed on the adhesive layer. The interlayer bonding member contains a thermoplastic polyimide.

Other aspects and advantages of the invention will be apparent from the following description and the appended claims.

### DISCLOSURE OF INVENTION

One or more embodiments of the present invention to provide a multilayer printed circuit board which has improved dielectric characteristics in the high-frequency range, is not easily affected by environmental changes, and has high reliability.

In one embodiment, a multilayer printed circuit board according to the present invention includes at least two printed wiring sheets laminated with an interlayer bonding member therebetween.

A printed wiring sheet, in accordance with one or more embodiments of the present invention, includes a non-thermoplastic polyimide film, an adhesive layer containing a thermoplastic polyimide disposed on at least one surface of the non-thermoplastic polyimide film, and a metal wiring layer disposed on the adhesive layer. The interlayer bonding member contains a thermoplastic polyimide. By combining the printed wiring sheet and the interlayer bonding member, excellent low-dielectric characteristics are exhibited even in the high-frequency range on the order of GHz or more. Furthermore, it is possible to exhibit advantages, such as excellent resistance to soldering heat, long-term heat resistance, and dimensional stability of the entire multilayer printed circuit board. The printed wiring sheet, the interlayer bonding member, and the method for producing the multilayer printed circuit board according to the present invention will be described below, in that order. A printed wiring sheet used for a multilayer printed circuit board in accordance with one or more embodiments of the present invention includes a non-thermoplastic polyimide film, an adhesive layer containing a thermoplastic polyimide disposed on at least one surface of the non-thermoplastic polyimide film, and a metal wiring layer disposed on the adhesive layer.

The non-thermoplastic film used for the printed wiring sheet is not particularly limited, and any of various types of resin films may be generally used.

As the polyimide film, a commercially available polyimide film, such as APICAL (manufactured by Kaneka Corporation), Kapton (manufactured by Toray-DuPont Company), or UPILEX (manufactured by Ube Industries, Ltd.), may be used. In view of a balance of physical properties, such as the coefficient of water absorption and dielectric characteristics, in the resulting printed wiring sheet, preferably, a polyimide film produced by reacting an acid dianhydride component containing an acid dianhydride represented by general formula (1): 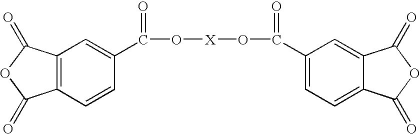
(wherein X represents a divalent organic group containing an aromatic ring) with an aromatic diamine is used. Although the expression mechanism has not been clarified yet, by using the acid dianhydride represented by general formula (1), the resulting polyimide film exhibits low water absorption and low-dielectric characteristics. The content of the acid dianhydride represented by general formula (1) is preferably 40 mole percent or more, and more preferably 50 mole percent or more, of the total acid dianhydride component. If the content is below the lower limit described above, in some cases, it may not possible to sufficiently obtain low water absorption and low-dielectric characteristics.

Examples of the acid dianhydride which may be used besides the acid dianhydride represented by general formula (1) include pyromellitic dianhydride, 2,3,6,7-naphthalenetetracarboxylic dianhydride, 3,3′,4,4′-biphenyltetracarboxylic dianhydride, 1,2,5,6-naphthalenetetracarboxylic dianhydride, 2,2′,3,3′-biphenyltetracarboxylic dianhydride, 3,3′,4,41-benzophenonetetracarboxylic dianhydride, 4,4′-oxyphthalic dianhydride, 2,2-bis(3,4-dicarboxyphenyl)propane dianhydride, 3,4,9,l0-perylenetetracarboxylic dianhydride, bis(3,4-dicarboxyphenyl)propane dianhydride, 1,1-bis (2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)ethane dianhydride, bis(3,4-dicarboxyphenyl)sulfone dianhydride, p-phenylenebis(trimellitic acid monoester anhydride), ethylenebis(trimellitic acid monoester anhydride), bisphenol A bis(trimellitic acid monoester anhydride), and analogs thereof.

Examples of the diamine include 4,4′-diaminodiphenylpropane, 4,4′-diaminodiphenylmethane, benzidine, 3,3′-dichlorobenzidine, 3,3′-dimethylbenzidine, 2,2′-dimethylbenzidine, 3,3′-dimethoxybenzidine, 2,2′-dimethoxybenzidine, 4,4′-diaminodiphenylsulfide, 3,3′-diaminodiphenyl sulfone, 4,4′-diaminodiphenyl sulfone, 4,4′-oxydianiline, 3,3′-oxydianiline, 3,4′-oxydianiline, 1,5-diaminonaphthalene, 4,4′-diaminodiphenyldiethylsilane, 4,4′-diaminodiphenylsilane, 4,4V-diaminodiphenylethylphosphine oxide, 4,4′-diaminodiphenyl N-methylamine, 4,4′-diaminodiphenyl N-phenylamine, 1,4-diaminobenzene(p-phenylenediamine), 1,3-diaminobenzene, 1,2-diaminobenzene, bis{4-(4-aminophenoxy)phenyl}sulfone, bis{4-(3-aminophenoxy)phenyl}sulfone, 4,4′-bis(4-aminophenoxy)biphenyl, 4,4′-bis(3-aminophenoxy)biphenyl, 1,3-bis(3-aminophenoxy)benzene, 1,3-bis(4-aminophenoxy)benzene, 3,3′-diaminobenzophenone, 4,4′-diaminobenzophenone, and analogs thereof.

A polyamic acid which is prepared by polymerization of the acid dianhydride component containing the acid dianhydride and the aromatic diamine component is formed into a film and imidized, and thereby, a polyimide film in accordance with an embodiment of the present invention is produced. The apparatuses and conditions used in the polymerization, film formation, and imidization steps are not particularly limited, and commonly known apparatuses and conditions may be used. Furthermore, an inorganic or organic filler may be incorporated as a lubricant, and in order to improve adhesion strength, the surface of the film may be subjected to various types of treatment, such as corona treatment or plasma treatment.

In order to use the multilayer printed circuit board according to an embodiment of the present invention stably in high-frequency applications, preferably, the insulating layer (non-thermoplastic film+adhesive layer) has a dielectric constant of 3.4 or less and a dielectric loss tangent of 0.010 or less at 12.5 GHz.

In order to make the circuit board less susceptible to the environment and to achieve stable low-dielectric characteristics, the coefficient of water absorption of the insulating layer may be controlled. Specifically, the coefficient of water absorption of the insulating layer (insulating film+adhesive layer) is preferably 1.6% or less, and particularly preferably 1.4% or less. If the coefficient of water absorption exceeds the upper limit described above, the amount of water absorbed into the insulating layer in the high-humidity environment increases, which may result in difficulty in exhibiting low-dielectric characteristics.

By limiting the coefficient of water absorption in the range described above, the influence of the environment can be reduced and stable low-dielectric characteristics can be achieved. Specifically, when measurement is performed at 12.5 GHz after samples of the insulating layer are left to stand for 12 hours, respectively, under the conditions of 20° C. and 40% R.H., 20° C. and 60% R.H., and 20° C. and 80% R.H., the insulating layer of each sample has a dielectric constant of 3.4 or less and a dielectric loss tangent of 0.010 or less. If the dielectric constant and the dielectric loss tangent exceed the above ranges in any one of the environments or in all the environments described above, it may become difficult to use the product stably in the high-frequency range.

In one or more embodiments, the non-thermoplastic polyimide film is defined as a polyimide film that is not fused and retains the shape of the film when heated at about 450° C. to 500° C.

Preferably, the adhesive layer contains a thermoplastic polyimide from the standpoints of low-dielectric characteristics and excellent balance between low-dielectric characteristics and other physical properties, such as heat resistance. Preferred examples of the thermoplastic polyimide to be contained in the adhesive layer include thermoplastic polyimides, thermoplastic polyamide-imides, thermoplastic polyetherimides, and thermoplastic polyesterimides. Among them, as in the insulating film, in view of excellence in low water absorption and low-dielectric characteristics, particularly preferred are thermoplastic polyesterimides containing ester bonds in their structures.

In one or more embodiments, the thermoplastic polyimide used for bonding the metal wiring layer and the insulating film is required to have compression set in a temperature range of 10° C. to 400° C. (heating rate: 10° C./min) in thermal mechanical analysis (TMA) using the compression mode (probe diameter: 3 mm, load: 5 g).

When a wiring layer is formed by bonding of a metal foil, such as a copper foil, using an existing apparatus, preferably, the thermoplastic polyimide of an embodiment of the present invention has a glass transition temperature (Tg) in a range of 150° C. to 300° C. If the Tg exceeds the above range, the temperature that develops adhesiveness also increases, and it may become difficult to perform working using the existing apparatus. If the Tg is below the above range, there is a possibility that the heat resistance of the adhesive layer may be decreased. Additionally, the Tg can be determined from the inflection point of the storage modulus measured by dynamic mechanical analyzer (DMA).

With respect to the production of the polyamic acid, which is a precursor of the thermoplastic polyimide used in an embodiment of the present invention, commonly known apparatuses, reaction conditions, etc., may be used. An inorganic or organic filler may be incorporated as required.

The printed wiring sheet used for the multilayer printed circuit board according to an embodiment of the present invention includes the insulating film, an adhesive layer containing a thermoplastic polyimide disposed on at least one surface of the insulating film, and a metal wiring layer disposed on the adhesive layer. The metal wiring layer is produced by a method in which a metal foil is bonded to an insulating film with an adhesive layer therebetween, and then unwanted parts of the metal foil layer are removed by etching, or a method in which a metal layer for a circuit pattern is formed on a surface of an adhesive layer by electroless and electrolytic plating. In the latter method, a process may be used in which, after a metal foil is bonded to the surface of the adhesive layer, the entire surface is etched, and the surface to which a roughed coarsened surface of the metal foil has been transferred is subjected to electroless and electrolytic plating. The latter method can be preferably used for forming circuit patterns by the additive process, and particularly preferably used when fine wiring are required to be formed. The metal foil is not particularly limited. In electronic device and electrical device applications, examples of the metal foil which may be used include foils composed of copper or copper alloys, stainless steel or alloys thereof, nickel or nickel alloys (including 42 alloys), and aluminum or aluminum alloys. Copper foils, such as rolled copper foils and electrolytic copper foils, are generally used for printed wiring sheets. Such copper foils can also be preferably used in an embodiment of the present invention. Additionally, a rust preventive layer, a heat-resistant layer, or an adhesive layer may be provided by coating on the surface of the metal foil. The thickness of the metal foil is not particularly limited, and the metal foil may be of any thickness as long as its function can be carried out sufficiently according to the application. With respect to etching conditions for the metal foil, those in any known method can be used.

Examples of the method for bonding a metal foil to an insulating film include a method in which a single-layer adhesive sheet is formed, and then an insulating film and a metal foil are laminated with the adhesive sheet, followed by thermocompression bonding; a method in which an adhesive layer is formed on a metal foil, and the resulting laminate and an insulating film are bonded to each other; and a method in which an adhesive layer is formed on an insulating film, and the resulting laminate and a metal foil are bonded to each other. Among these methods, with respect to the use of the second or the third method, if a polyamic acid, which is a precursor of the thermoplastic polyimide contained in the adhesive layer, is completely imidized, in some cases, the solubility in an organic solvent may decrease, and thus it may become difficult for the adhesive layer to adhere to the metal foil or the insulating film. From this standpoint, more preferably, a solution containing a polyamic acid, which is a precursor of the thermoplastic polyimide, is prepared, the solution is applied to the metal foil or the insulating film, and then imidization is performed. The imidization may be performed by a thermal cure method or a chemical cure method. In the chemical cure method, in some cases, the heating conditions must be set so that a chemical conversion agent, etc., is removed without thermally degrading the adhesive layer. Therefore, the imidization by the thermal cure method is more preferable. This does not apply to a case in which a thermoplastic polyimide that is soluble in an organic solvent is used.

With respect to the thicknesses of the non-thermoplastic polyimide film and the adhesive layer, an adjustment may be appropriately made so that the total thickness is set according to the application. Preferably, the total thickness of the non-thermoplastic polyimide film and the adhesive layer in the printed wiring sheet is 30 μm or less.

Furthermore, the coefficient of water absorption of the insulating layer (non-thermoplastic polyimide film+adhesive layer) is greatly influenced by the thickness ratio as well as by the coefficient of water absorption of each of the insulating film and the adhesive layer. Therefore, the thicknesses are preferably determined by taking these factors into account.

Examples of the apparatus used for bonding the metal foil include, but are not limited to, a single-platen press, a multi-platen press, a double belt press, and a thermal roll laminator. Conditions for bonding may be appropriately selected in consideration of the glass transition temperature of the adhesive layer, etc.

A material for the interlayer bonding member used in embodiments of the present invention is required to have low-dielectric characteristics in the high-frequency range, heat resistance, i.e., resistance to high-temperature treatment, such as a soldering step, dimensional stability, and flowability required for embedding wiring patterns. Therefore, the interlayer bonding member used in embodiments the present invention must contain a thermoplastic polyimide resin.

The interlayer bonding member of an embodiment of the present invention preferably comprises a thermosetting resin composition including a thermoplastic polyimide resin component (A) containing at least one thermoplastic polyimide resin, an epoxy resin component (B) containing at least one epoxy resin, and an epoxy curing agent component (C) containing at least one epoxy curing agent.

As the interlayer adhesive, in view of excellent dielectric loss tangent and resin flowability during lamination, the compounding ratio of the thermoplastic polyimide resin component (A) to the total of the epoxy resin component (B) and the epoxy curing agent component (C), i.e., (A)/[(B)+(C)], by mass, is preferably 0.4 to 2.0, more preferably 0.70 to 1.35, and still more preferably 0.8 to 1.3.

In the interlayer bonding member used in an embodiment of the present invention, by incorporating the thermoplastic polyimide resin component (A) containing at least one thermoplastic polyimide resin, heat resistance is imparted to the thermosetting resin composition, and flexibility, excellent mechanical characteristics, and chemical resistance are imparted to a cured resin obtained by curing the thermosetting resin composition. Furthermore, excellent dielectric characteristics, i.e., low-dielectric constant and low dielectric loss tangent, in the high-frequency range can be imparted. Although the thermoplastic polyimide resin is not particularly limited, the thermoplastic polyimide resin must be soluble in an organic solvent in order to be mixed with the thermosetting resin and must have low-dielectric characteristics in order to compensate for increases in the dielectric constant and the dielectric loss tangent due to the incorporation of the thermosetting resin. In order to balance the characteristics described above, preferably at least one polyimide resin contained in the polyimide resin component (A) is produced by reacting an acid dianhydride component containing an acid dianhydride represented by general formula (2): 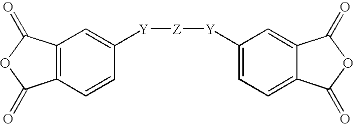
(wherein Y represents —O— or —C(═O)O— and Z represents a divalent organic group) in an amount of 50 mole percent or more with an aromatic diamine component. The process and conditions for producing the polyimide resin are not particularly limited, and any known process and conditions may be used.

Other examples of the acid dianhydride component include pyromellitic dianhydride, 3,3′,4,4′-benzophenonetetracarboxylic dianhydride, 3,3′,4,4′-biphenylsulfonetetracarboxylic dianhydride, 1,4,5,8-naphthalenetetracarboxylic dianhydride, 2,3,6,7-naphthalenetetracarboxylic dianhydride, 3,3′,4,4′-biphenyl ether tetracarboxylic dianhydride, 3,3′,4,4′-dimethyldiphenylsilanetetracarboxylic dianhydride, 3,3′,4,4′-tetraphenylsilanetetracarboxylic dianhydride, 1,2,3,4-furantetracarboxylic dianhydride, 4,4′-bis (3,4-dicarboxyphenoxy)diphenylsulfide dianhydride, 4,4′-bis(3,4-dicarboxyphenoxy)diphenyl sulfone dianhydride, 4,4′-bis(3,4-dicarboxyphenoxy)diphenylpropane dianhydride, 3,3′,4,4′-hexafluoroisopropylidenediphthalic dianhydride, 3,3′,4,4′-biphenyltetracarboxylic dianhydride, bis(phthalic acid)phenylphosphine oxide dianhydride, p-phenylene-bis(triphenylphthalic acid) dianhydride, m-phenylene-bis(triphenylphthalic acid) dianhydride, 4,4′-bis(triphenylphthalic acid)-diphenyl ether dianhydride, and 4,4′-bis(triphenylphthalic acid)-diphenylmethane dianhydride.

Other examples of the diamine component include p-phenylenediamine, m-phenylenediamine, 4,4′-diaminodiphenylmethane, 4,4′-diaminodiphenylethane, 4,4′-diaminodiphenyl ether, 4,4′-diaminodiphenylsulfide, 4,4′-diaminodiphenyl sulfone, 1,5-diaminonaphthalene, 3,3′-dimethyl-4,4′-diaminobiphenyl, 5-amino-1-(4′-aminophenyl)-1,3,3-trimethylindane, 6-amino-1-(4′-aminophenyl)-1,3,3-trimethylindane, 4,4′-diaminobenzanilide, 3,5-diamino-3′-trifluoromethylbenzanilide, 3,5-diamino-4′-trifluoromethylbenzanilide, 3,4′-diaminodiphenyl ether, 2,7-diaminofluorene, 2,2-bis(4-aminophenyl)hexafluoropropane, 4,4′-methylene-bis(2-chloroaniline), 2,2′,5,5′-tetrachloro-4,4′-diaminobiphenyl, 2,2′-dichloro-4,4′-diamino-5,5′-dimethoxybiphenyl, 3,3′-dimethoxy-4,4′-diaminobiphenyl, 4,4′-diamino-2,2′-bis(trifluoromethyl)biphenyl, 2,2-bis[4-(4-aminophenoxy)phenyl]propane, 2,2-bis [4-(4-aminophenoxy)phenyl]hexafluoropropane, 1,4-bis(4-aminophenoxy)benzene, 4,4′-bis(4-aminophenoxy)-biphenyl, 1,3-bis(4-aminophenoxy)benzene, 9,9-bis(4-aminophenyl)fluorene, 4,4′-(p-phenyleneisopropylidene)bisaniline, 4,4′-(m-phenyleneisopropylidene)bisaniline, 2,2′-bis[4-(4-amino-2-trifluoromethylphenoxy)phenyl]hexafluoropropane, and 4,4′-bis[4-(4-amino-2-trifluoromethyl)phenoxy]-octafluorobiphenyl.

As the epoxy resin component (B), a compound having at least two reactive epoxy groups per molecule is preferably used in an embodiment of the present invention.

Examples of the epoxy resin include, but are not limited to, epoxy resins, such as bisphenol epoxy resins, bisphenol A novolac epoxy resins, biphenyl epoxy resins, phenol novolac epoxy resins, alkylphenol novolac epoxy resins, polyglycol epoxy resins, alicyclic epoxy resins, cresol novolac epoxy resins, glycidylamine epoxy resins, naphthalene epoxy resins, urethane-modified epoxy resins, rubber-modified epoxy resins, and epoxy-modified polysiloxanes; resins obtained by halogenating theses epoxy resins; and crystalline epoxy resins with melting points. These epoxy resins may be used alone or in combination of two or more.

Among the epoxy resins described above, more preferably used are epoxy resins having at least one aromatic ring and/or aliphatic ring in their molecular chains, biphenyl epoxy resins with the biphenyl skeleton, naphthalene epoxy resins with the naphthalene skeleton, and crystalline epoxy resins with melting points. These epoxy resins are readily available and highly compatible with the components (A), (B), and (C), and can impart excellent heat resistance and insulating properties to the cured resin.

Preferably, the epoxy resin used for the epoxy resin component (B) has high purity whatever epoxy resin is selected from the group described above. Thereby, in the resulting thermosetting resin composition and curable resin, highly reliable electrical insulation can be achieved. In an embodiment of the present invention, the content of halogen and alkali metal in the epoxy resin is used as the basis for high purity. Specifically, the content of halogen and alkali metal in the epoxy resin is preferably 25 ppm or less, and more preferably 15 ppm or less, when extracted at 120° C. and 2 atmospheric pressure. If the content of halogen and alkali metal is higher than 25 ppm, the reliability of electrical insulation is impaired in the cured resin.

As the epoxy curing agent component (C) included in the interlayer bonding member, any compound having at least two active hydrogen atoms per molecule can be used without limitation. Examples of the active hydrogen source include an amino group, a carboxyl group, a phenolic hydroxyl group, an alcoholic hydroxyl group, and a thiol group. A compound having such a functional group can be used as the epoxy curing agent component (C) of an embodiment of the present invention. Among these, amino group-containing amine epoxy curing agents and phenolic hydroxyl group-containing polyphenol epoxy curing agents can be preferably used in view of excellent balance of properties of the thermosetting resin composition of an embodiment of the present invention.

Examples of the polyphenol epoxy curing agents that may be used in an embodiment of the present invention include phenol novolac, xylylene novolac, bisphenol A novolac, triphenylmethane novolac, biphenyl novolac, and dicyclopentadienephenol novolac.

Furthermore, in an embodiment of the present invention, an amine epoxy curing agent can be preferably used as the epoxy curing agent component (C). The amine epoxy curing agent can impart good resin flowability to the thermosetting resin composition and good heat resistance to the cured resin.

The amine epoxy curing agent component used in an embodiment of the present invention is required to have at least one amine compound. Examples of the amine epoxy curing agent component include, but are not limited to, monoamines, such as aniline, benzylamine, and aminohexane; various types of diamines; and polyamines, such as diethylenetriamine, tetraethylenepentamine, and pentaethylenehexamine. Among these amines, from the standpoints of excellent heat resistance and ease of controlling curability, aromatic diamines are preferably used.

The interlayer bonding member according to an embodiment of the present invention may also contain other components (D), as required, in addition to the components (A) to (C). The other components (D) are not particularly limited. Specific examples of the other components (D) include a curing accelerator (D-1) for accelerating the reaction between the epoxy resin composition and the epoxy curing agent composition, an inorganic filler (D-2), and a thermosetting resin component (D-3).

The curing accelerator (D-1) used in an embodiment of the present invention is not particularly limited. Examples thereof include imidazole compounds; phosphine compounds, such as triphenylphosphine; amine compounds, such as tertiary amines, trimethanolamine, triethanolamine, and tetraethanolamine; and borate compounds, such as 1,8-diaza-bicyclo[5,4,0]-7-undecenium tetraphenyl borate. These curing accelerators may be used alone or in combination of two or more. Among these, imidazole compounds are preferable. The imidazole compounds may be used alone or in combination of two or more.

The amount of use (mixing ratio) of the curing accelerator is not particularly limited as long as it is in a range that can accelerate the reaction between the epoxy resin component and the epoxy curing agent and that does not impair the dielectric characteristics of the curable resin. Generally, the curing accelerator is used in an amount of preferably 0.01 to 10 parts by weight, and more preferably 0.1 to 5 parts by weight, relative to 100 parts by weight of the total amount of the epoxy resin component (C).

Among these compounds, in view of excellent circuit embedding properties, availability, solubility in solvent, etc., 2-ethyl-4-methylimidazole, 2-phenyl-4-methylimidazole, 2,4-diamino-6-[2′-undecylimidazole-(1′)]-ethyl-s-triazine are more preferably used.

The inorganic filler (D-2) is not particularly limited. Examples thereof include fused silica, crystalline silica, and alumina. These may be used alone or in combination. Among these, spherical fused silica can be preferably used because it does not substantially affect the resin flowability adversely, which is an advantage of one or more embodiments of the present invention, and it decreases the coefficient of thermal expansion entirely. In one or more embodiments, the inorganic filler may be preferably used in an amount of about 1 to 200 parts by weight, and more preferably about 30 to 100 parts by weight, relative to 100 parts by weight of the resin composition.

The thermosetting component (D-3) is not particularly limited. Examples thereof include thermosetting resins, such as bismaleimide resins, bisallylnadimide resins, acrylic resins, methacrylic resins, hydrosilyl curable resins, allyl curable resins, and unsaturated polyester resins; and reactive side-chain group-containing thermosetting polymers which contain a reactive group, such as an allyl group, a vinyl group, an alkoxysilyl group, or a hydrosilyl group, at the side chain or at the terminus of the polymer chains. These thermosetting components may be used alone or in combination of two or more. By incorporating the thermosetting component, it is possible to improve characteristics, such as adhesiveness, heat resistance, and workability, of the resulting thermosetting resin composition and the cured resin.

The amount of use (mixing ratio) of the thermosetting component is not particularly limited as long as it is in a range that can exhibit the effect of improving the characteristics and that does not impair the dielectric characteristics of the curable resin.

With respect to the interlayer bonding member of an embodiment of the present invention, by appropriately adjusting the compositions and mixing ratio of the components as described above, excellent circuit embedding properties are shown during processing, and excellent dielectric characteristics are shown in the high-frequency range after curing.

The interlayer bonding member of an embodiment of the present invention may be supplied in the form of a solution, applied to the printed wiring sheet, and semi-cured for use. Alternatively, the interlayer bonding member may be preliminarily formed into a sheet and then supplied for use. In view of ease of laminating wiring sheets, the latter method is preferable.

In order to form a sheet of the interlayer bonding member, a solution in which the components (A) to (C), or (A) to (D), depending on the case, are dissolved must be prepared. The method for the preparation is not particularly limited. The components each may be dissolved in a suitable solvent to form a solution, and the resulting solutions may be mixed. Any solvent that can dissolve the thermosetting resin composition or the components (A) to (D) may be used without limitation. Preferably, the solvent has a boiling point of 150° C. or less. Preferred examples of the solvent include ethers, such as cyclic ethers, e.g., tetrahydrofuran, dioxolane, and dioxane; and linear ethers, e.g., ethylene glycol dimethyl ether, triglyme, diethylene glycol, ethyl cellosolve, and methyl cellosolve. Furthermore, mixed solvents of these ethers and other solvents, such as toluene, xylenes, glycols, N,N-dimethylformamide, N,N-dimethylacetamide, N-methylpyrrolidone, cyclic siloxane, and linear siloxane, can also be preferably used. These solvents may be used alone or in combination of two or more.

The method for forming the sheet is not particularly limited. Usually, the solution is cast onto or applied to a surface of a film base (support), and then the resin solution is dried to form a film. In the sheet formed by this method, the thermosetting resin component is in a semi-cured state (stage B). By peeling off the semi-cured sheet from the support, a sheet of the interlayer bonding member is obtained.

The film base used as the support is not particularly limited, and a known resin film may be suitably used. Furthermore, a support other than the film base may be used. As such a support, for example, a drum or endless belt may be used.

The thickness of the interlayer bonding member is not particularly limited and can be set appropriately depending on the application. A multilayer printed circuit board in accordance with one or more embodiments of the present invention is produced by thermocompression bonding at least two printed wiring sheets described above with the interlayer bonding member therebetween. The number of laminations is not particularly limited and can be selected appropriately depending on the application. A printed wiring sheet other than the one described above may be partially used to an extent that does not impair the characteristics of the entire multilayer board.

Although not particularly limited, the treatment temperature in the thermocompression bonding treatment is preferably in a range of 50° C. to 250° C., more preferably in a range of 60° C. to 200° C., and still more preferably in a range of 80° C. to 180° C. If the treatment temperature exceeds 250° C., there may be a case in which the interlayer bonding member is cured during the thermocompression bonding treatment and lamination cannot be performed satisfactorily. If the treatment temperature is less than 50° C., the flowability of the interlayer bonding member is decreased, resulting in difficulty in embedding conductive circuit patterns.

The interlayer bonding member serves as a protective material for protecting conductive circuit patterns or an interlayer insulating material in the multilayer printed circuit board. Therefore, preferably, after circuit patterns are embedded, the interlayer bonding member is completely cured by thermal curing or the like. The specific method for thermal curing is not particularly limited. Thermal curing may be performed under the conditions which allow sufficient curing of the resin layer, i.e., the thermosetting resin composition.

When the interlayer bonding member is cured, in order to allow the curing reaction of the epoxy resin component (B) to proceed thoroughly, post-heating treatment is preferably performed after the metal layer and the resin layer have been bonded to each other. Although the conditions for post-heating treatment are not particularly limited, heat treatment is preferably performed in a temperature range of 150° C. to 200° C. for 10 minutes to 3 hours.

With respect to the lamination procedure, either a method in which after all the layers are laminated, the interlayer bonding member is cured, or a method in which lamination and curing are performed on a layer-by-layer basis may be employed. Furthermore, in the multilayer printed circuit board, it is necessary to form via-holes for electrical connection in the perpendicular direction. In a multilayer printed circuit board according a preferred embodiment of the present invention, via-holes are formed by a known method, for example, using a laser, by mechanical drilling, or by punching, and electrical conduction is achieved by a known method, for example, by electroless plating, using conductive paste, or by direct plating.

Multilayer printed circuit boards produced by the materials and methods described above in accordance with one or more embodiments of the present invention have excellent low-dielectric characteristics in the high-frequency range and can cope with the increases in frequencies of electrical signals. Thus, it is possible to greatly contribute to the improvement in the processing ability of electronic devices.

Furthermore, the multilayer printed circuit board produced by combining the specific printed wiring sheets and the interlayer bonding member of an embodiment of the present invention can exhibit excellent resistance to soldering heat. Specifically, it is possible to produce a multilayer printed circuit board in which blistering, whitening, and delamination do not occur between the layers even if the circuit board is left to stand under the conditions of 40° C. and 90% R.H. for 96 hours and then dipped in a solder bath at 250° C. for 10 seconds.

Furthermore, excellent long-term heat resistance can be imparted to the interlayer bonding member. Specifically, it is possible to produce a multilayer printed circuit board in which the retention of interlayer adhesion strength is 70% or more after the multilayer printed circuit board is left to stand at 150° C. for 500 hours.

Furthermore, it is possible to produce a multilayer printed circuit board with excellent dimensional stability, and the ratio of change in dimensions in the entire multilayer printed circuit board can be set in a range of −0.20% to +0.20% after the multilayer printed circuit board is left to stand at 250° C. for 30 minutes.

In addition to the excellent dielectric characteristics, resistance to soldering heat, long-term heat resistance, and dimensional stability, it is possible to decrease the thickness of the multilayer printed circuit board. Consequently, the multilayer printed circuit board of an embodiment of the present invention can be suitably used in the high-frequency, high-density mounting region. With respect to the multilayer printed circuit boards of one or more embodiments of the present invention, applications are not limited to those described above. The multilayer printed circuit boards of one or more embodiments of the present invention can also be used suitably in the applications requiring reliability with which conventional multilayer printed circuit boards cannot cope.

### EXAMPLES

While embodiments of the present invention will be described specifically based on the examples below, it is to be understood that the present invention is not limited thereto.

In the synthesis examples, examples, and comparative examples described below, thermoplasticity or non-thermoplasticity of the polyimide, the dielectric constant and dielectric loss tangent, the glass transition temperature of the adhesive film, the melt viscosity of the interlayer bonding member, circuit embedding properties, and the resistance to soldering heat, long-term heat resistance, and dimensional stability of the multilayer circuit board were determined, measured, or evaluated by the methods described below.

(Determination for Thermoplasticity 1)

Thermoplasticity of a polyimide used for an adhesive layer of a printed wiring sheet was determined using TMA120C manufactured by Seiko Electronics Inc., in the compression mode (probe diameter: 3 mm) at a load of 5 g, in which a film was heated to 10° C. to 400° C. at 10° C./min and then cooled to 10° C. to check whether or not compression set occurred.

(Determination for Thermoplasticity 2)

Thermoplasticity of a polyimide used for an interlayer bonding member was determined as in the determination for thermoplasticity 1 using TMA120C manufactured by Seiko Electronics Inc., in the compression mode (probe diameter: 3 mm) at a load of 5 g, in which a film was heated to 10° C. to 400° C. at 10° C./min and then cooled to 10° C. to check whether or not compression set occurred.

(Determination for Non-Thermoplasticity)

Non-thermoplasticity of a polyimide film used for a printed wiring sheet was determined by visually checking whether or not a film retains its shape without being fused after it was heated at 450° C. for 1 minute.

(Dielectric Constant and Dielectric Loss Tangent)

The dielectric constant and dielectric loss tangent were measured using a molecular orientation analyzer Model MOA-2012A manufactured by KS Systems Co., Ltd. under the conditions described below.
Measured frequency: 12.5 GHz
Measured angles: 0 degree, 45 degrees, 90 degrees

The dielectric constant and the dielectric loss tangent were measured at the three angles and the average values thereof were determined as the dielectric constant and the dielectric loss tangent of the material measured.

(Glass Transition Temperature)

The glass transition temperature was determined from the inflection point of the storage modulus measured with a DMS200 manufactured by Seiko Instruments Inc. at a heating rate of 3° C./min in a range from room temperature to 400° C.

(Melt Viscosity)

With respect to a resin sheet before thermal curing, using a dynamic viscoelasticity analyzer (CVO, manufactured by Bohling Corp.) in the shear mode, the complex viscosity (Pa·S) was measured under the conditions described below, and the complex viscosity was converted into the melt viscosity (poise). The melt viscosity of each resin sheet was evaluated based on the minimum viscosity in a range of 60° C. to 200° C.
Measured frequency: 1 Hz
Heating rate: 12° C./min
Sample measured: circular resin sheet with a diameter of 3 mm

(Circuit Embedding Properties)

A sheet of an interlayer bonding member (50 μm thick) was interposed between a circuit-forming surface of a printed wiring sheet having a circuit with a thickness of 18 μm, a circuit width of 50 μm, and a circuit spacing of 50 μm (refer to Synthesis Examples 8 and 9 below) and a glossy surface of a copper foil (Item No. BHY22BT, manufactured by Japan Energy Corporation) 18 μm in thickness, and heat and pressure were applied for one hour at 180° C. and 3 MPa to produce a laminate. The copper foil of the resulting laminate was chemically removed using an iron (III) chloride-hydrochloric acid solution. The exposed surface of the resin sheet was visually observed using an optical microscope (magnification: 50 times) to check whether or not bubbles were included in the space between the circuits.

Laminability was evaluated according to the following criteria:
Satisfactory (◯): No inclusion of bubbles (portions not filled with the resin) was observed in the space between the circuits.
Unsatisfactory (×): Inclusion of bubbles was observed.

(Resistance to Soldering Heat)

Two printed wiring sheets each having a circuit with a thickness of 18 μm, a circuit width of 50 μm, and a circuit spacing of 50 μm (refer to Synthesis Examples below) were stacked with a sheet of an interlayer bonding member (50 μm thick) therebetween, and heat and pressure were applied for one hour at 180° C. and 3 MPa to produce a laminate. The resulting laminate was cut into a square of 50 mm×50 mm, dried and dehumidified at 120° C. for 30 minutes, and then left to stand for 96 hours in an environmental testing chamber controlled at 40° C. and 90% R.H.

The laminate which had absorbed moisture was dipped in a solder bath at 250° C. for 10 seconds. After dipping, the wires in the outermost layer and the solder attached to the wires were removed by etching. The laminate after etching was visually checked and evaluated according to the following criteria:
Satisfactory (◯): No appearance defect was observed in interlayer bonding member layer.
Unsatisfactory (×): Appearance defects, such as bubbling, whitening, and delamination, were observed in interlayer bonding member layer.

(Long-Term Heat Resistance)

A 50-mm-square laminate, which was prepared as in the evaluation of resistance to soldering heat, was left to stand in an oven at 150° C. for 500 hours. The heated laminate was cut along the circuit into a strip with a width of 10 mm. The insulating layers of the wiring sheets on both sides were each clamped with an air chuck, and a 180° peel test was carried out.

A similar peel test was carried out with respect to a laminate before placement in an oven set at 150° C. The peel strength of the laminate heated in the oven relative to the peel strength (100) before placement in the oven was calculated, and thereby the retention ratio (%) was determined.

(Ratio of Change in Dimensions)

Wirings on the surface of outermost layer of a 50-mm-square laminate prepared as in the resistance to soldering heat evaluation were removed by etching. The resulting laminate was left to stand in a thermo-hygrostatic room at 23° C. and 60% R.H. for 24 hours. Subsequently, in the thermo-hygrostatic room, using an optical microscope, the pitch (width+spacing) of the circuit embedded in the interlayer bonding member layer was visually measured across the entire width, and the average circuit pitch was calculated.

Subsequently, the laminate measured was left to stand in an oven at 150° C. for 30 minutes. With respect to the resulting laminate, the average circuit pitch was calculated in the same manner as that described above. The ratio of change in dimensions was calculated according to the expression below, where D1 is the average pitch before heating and D2 is the average pitch after heating.
Ratio of change in dimensions=(D2−D1)/D1×100(%)

### Synthesis Example 1

### Synthesis of Thermoplastic Polyimide Precursor

A 2,000-mL glass flask was charged with 780 g of DMF and 117.2 g of bis[4-(4-aminophenoxy)phenyl]sulfone (hereinafter also referred to as “BAPS”), and 71.7 g of 3,3′,4,4′-biphenyltetracarboxylic dianhydride (hereinafter also referred to as “BPDA”) was gradually added thereto under stirring in a nitrogen atmosphere. Subsequently, 5.6 g of 3,3′,4,4′-ethylene glycol dibenzoate tetracarboxylic dianhydride (hereinafter also referred to as “TMEG”) was added thereto, and stirring was performed for 30 minutes in an ice bath. A solution separately prepared by dissolving 5.5 g of TMEG in 20 g of DMF was gradually added to the reaction solution while monitoring the viscosity under stirring. Addition and stirring were stopped when the viscosity reached 3,000 poise. A polyamic acid solution was thereby prepared.

The resulting polyamic acid solution was cast onto a 25-μm-thick PET film (Cerapeel HP, manufactured by Toyo Metallizing Co., Ltd.) so as to have a final thickness of 20 μm, and drying was performed at 120° C. for 5 minutes. The dried self-supporting film was separated from the PET and fixed on a metal pin frame, and drying was performed at 150° C. for 5 minutes, at 200° C. for 5 minutes, at 250° C. for 5 minutes, and at 350° C. for 5 minutes. Upon checking, it was found that the resulting single-layer sheet had thermoplasticity. Furthermore, the glass transition temperature of the single-layer sheet was measured to be 270° C.

### Synthesis Example 2

### Synthesis of Thermoplastic Polyimide Precursor

A 2,000-mL glass flask was charged with 780 g of DMF and 103.9 g of 2,2-bis[4-(4-aminophenoxy)phenyl]propane (hereinafter also referred to as “BAPP”), and 28.6 g of benzophenonetetracarboxylic dianhydride (hereinafter also referred to as “BTDA”) was gradually added thereto under stirring in a nitrogen atmosphere. Subsequently, 65.4 g of 3,3′,4,4′-ethylene glycol dibenzoate tetracarboxylic dianhydride (hereinafter also referred to as “TMEG”) was added thereto, and stirring was performed for 30 minutes in an ice bath. A solution separately prepared by dissolving 2.1 g of TMEG in 20 g of DMF was gradually added to the reaction solution while monitoring the viscosity under stirring. Addition and stirring were stopped when the viscosity reached 3,000 poise. A polyamic acid solution was thereby prepared.

The resulting polyamic acid solution was cast onto a 25-μm-thick PET film (Cerapeel HP, manufactured by Toyo Metallizing Co., Ltd.) so as to have a final thickness of 20 μm, and drying was performed at 120° C. for 5 minutes. The dried self-supporting film was separated from the PET and fixed on a metal pin frame, and drying was performed at 150° C. for 5 minutes, at 200° C. for 3 minutes, at 250° C. for 3 minutes, and at 300° C. for 2 minutes. Upon checking, it was found that the resulting single-layer sheet had thermoplasticity. Furthermore, the glass transition temperature of the single-layer sheet was measured to be 190° C.

### Synthesis Example 3

### Synthesis of Thermoplastic Polyimide

Into a 2,000-mL glass flask charged with DMF, 0.95 equivalents of 1,3-bis(3-aminophenoxy)benzene (hereinafter also referred to as “APB”) and 0.05 equivalents of 3,3′-dihydroxy-4,4′-diaminobiphenyl (hereinafter also referred to as “HAB”) were added, and stirring was performed in a nitrogen atmosphere for dissolution to prepare a DMF solution. Next, after the inside of the flask was purged with nitrogen, the DMF solution was stirred under cooling in an ice bath, and 1 equivalent of 4,4′-(4,4′-isopropylidenediphenoxy)bisphthalic anhydride (hereinafter also referred to as “IPBP”) was added thereto. Stirring was further performed for 3 hours, and thereby a polyamic acid solution was prepared. The amount of DMF used was set so that the charge ratio of APB, HAB, and IPBP monomers was 30% by weight.

The polyamic acid solution in an amount of 300 g was transferred to a pan coated with fluororesin, reduced pressure heating was performed in a vacuum oven for 3 hours at 200° C. and 5 mmHg (about 0.007 atmospheric pressure, about 5.65 hPa), and thereby a polyimide resin was obtained.

The resulting polyimide resin was dissolved in dioxolane so as to have an SC of 30%. The resulting solution was cast onto a PET film (Cerapeel HP, manufactured by Toyo Metallizing Co., Ltd.) and dried at 80° C. for 5 minutes. The dried sheet was separated from the PET and fixed on a metal frame, and drying was performed at 120° C. for 5 minutes, at 150° C. for 5 minutes, and at 200° C. for 5 minutes. Thereby, a film with a thickness of 20 μm was obtained. Upon checking, it was found that the resulting single-layer sheet had thermoplasticity. Furthermore, the glass transition temperature of the single-layer sheet was measured to be 160° C.

### Synthesis Example 4

### Synthesis of Polyimide Film

With a reaction system being retained at 5° C., 4,4′-diaminodiphenyl ether (hereinafter also referred to as “4,4′-ODA”) in an amount of 50 mole percent and para-phenylenediamine (hereinafter also referred to as “p-PDA”) in an amount of 50 mole percent were added to N,N′-dimethylacetamide (hereinafter also referred to as “DMAc”), followed by stirring for 30 minutes. Next, p-phenylene bis(trimellitic acid monoester anhydride) (hereinafter also referred to as “TMHQ”) in an amount of 50 mole percent was added thereto, and stirring was performed for 30 minutes. Then, pyromellitic dianhydride (hereinafter also referred to as “PMDA”) in an amount of 47 mole percent was added thereto, followed by stirring for 30 minutes.

Finally, a solution was prepared by dissolving 3 mole percent of PMDA in DMAc so that the solid concentration was 7%. This solution was gradually added to the reaction solution while monitoring the viscosity, and the polymerization was terminated when the viscosity reached 4,000 poise at 20° C. The solid content of the final solution was 18%.

The polymerization solution was cooled to about 0° C. An imidization accelerator was added thereto in an amount of 45% by weight to the polyamic acid solution, the imidization accelerator comprising 2 mole percent of acetic anhydride, 1 mole percent of isoquinoline, and 4 mole percent of DMAc relative to 1 mole of polyamic acid of the polyamic acid solution. Continuous stirring was performed with a mixer, and the mixture was extruded from a T-die and cast onto a stainless steel endless belt travelling 20 mm below the die. The resin film was heated at 130° C. for 100 seconds and separated from the endless belt. A self-supporting gel film was thereby obtained (volatile content: 54% by weight).

The resulting gel film was fixed to tenter clips, and drying and imidization were performed at 300° C. for 30 seconds, at 400° C. for 30 seconds, and at 500° C. for 30 seconds. A polyimide film with a thickness of 18 μm was thereby obtained.

### Synthesis Examples 5 to 10

### Formation of Sheet of Interlayer Bonding Member

In each Synthesis Example, the components were dissolved in dioxolane so as to satisfy the mixture ratio shown in Table 1, and thereby a resin solution (varnish), i.e., a thermosetting resin composition according to an embodiment of the present invention, was produced.

The resulting resin solution was cast onto a surface of a 125-μm-thick PET film (trade name: Cerapeel HP, manufactured by Toyo Metallizing Co., Ltd.) functioning as a support. Drying was performed by heating with a hot-air oven at 60° C., 80° C., 100° C., 120° C., and 140° C., each for 3 minutes. A double layer sheet including the PET film as a film base was thereby formed. By separating the PET film from the double layer sheet, a single-layer sheet (resin sheet before thermal curing) was obtained. The thickness of the resin sheet was 50 μm.

### Synthesis Example 11

### Production of Printed Wiring Sheet

The thermoplastic polyimide precursor solution prepared in Synthesis Example 1 was diluted with DMF to 7% solid content, and then applied to both surfaces of the polyimide film produced in Synthesis Example 4 so as to have a final thickness of 4 μm, followed by drying at 140° C. for 1 minute.

Subsequently, the thermoplastic polyimide precursor was imidized by passing the film, at a rate of 2.5 m/min, through a far-infrared oven controlled at 410° C. A double-sided adhesive film was thereby obtained.

A rolled copper foil (BHY-22B-T, manufactured by Japan Energy Corporation) with a thickness of 18 μm was disposed on each surface of the resulting double-sided adhesive film, and a polyimide film (APICAL 125NPI, manufactured by Kaneka Corporation) as a protective film was further disposed on each polyimide film. Thermal lamination was continuously performed with the tension of the adhesive film being set at 0.4 N/cm, and at a lamination temperature of 390° C., a lamination pressure of 196 N/cm (20 kgf/cm), and a laminating speed of 2.5 m/min. After lamination, the protective films were separated from both sides, and thereby a copper-clad laminate was produced.

The copper foil surfaces of the resulting copper-clad laminate were subjected to patterning, and thereby a printed wiring sheet having wiring patterns with a line width of 50 μm and a line spacing of 50 μm was produced.

### Synthesis Example 12

### Production of Printed Wiring Sheet

The thermoplastic polyimide precursor solution prepared in Synthesis Example 2 was diluted with DMF to 7% solid concentration, and then applied to both surfaces of the polyimide film produced in Synthesis Example 4 so as to have a final thickness of 4 μm, followed by drying at 140° C. for 1 minute.

Subsequently, the thermoplastic polyimide precursor was imidized by passing the film, at a rate of 2.5 m/min, through a far-infrared oven controlled at 330° C. A double-sided adhesive film was thereby obtained.

A rolled copper foil (BHY-22B-T, manufactured by Japan Energy Corporation) with a thickness of 18 μm was disposed on each surface of the resulting double-sided adhesive film, and a polyimide film (APICAL 125NPI, manufactured by Kaneka Corporation) as a protective film was further disposed on each side of the copper foil. Thermal lamination was continuously performed with the tension of the adhesive film being set at 0.4 N/cm, and at a lamination temperature of 320° C., a lamination pressure of 196 N/cm (20 kgf/cm), and a laminating speed of 2.5 m/min. After lamination, the protective films were separated from both sides, and thereby a copper-clad laminate was produced.

The copper foil surfaces of the resulting copper-clad laminate were subjected to patterning, and thereby a printed wiring sheet having wiring patterns with a line width of 50 μm and a line spacing of 50 μm was produced.

### Synthesis Example 13

### Production of Printed Wiring Sheet

An epoxy resin solution was prepared by dissolving 30 g of an epoxy resin (Epikote 1032H60, manufactured by Yuka Shell Epoxy Co., Ltd.) in 70 g of dioxolane. The resulting solution was cast onto a surface of a 25-μm-thick polyimide film (APICAL 25NPP, manufactured by Kaneka Corporation) so as to have a coating thickness of 5 μm after drying, and drying was performed at 80° C. for 2 minutes. The other surface of the polyimide film was similarly treated, and drying was performed at 120° C. for 2 minutes. An adhesive film was there by obtained.

A rolled copper foil (BHY-22B-T, manufactured by Japan Energy Corporation) with a thickness of 18 μm was disposed on each surface of the resulting adhesive film, and a polyimide film (APICAL 125NPI, manufactured by Kaneka Corporation) as a protective film was further disposed on each polyimide film. Pressing was performed at 200° C. and 3 MPa for 5 minutes. Post-curing treatment was then performed at 180° C. for 3 hours. A copper-clad laminate was thereby produced.

The copper foil surfaces of the resulting copper-clad laminate were subjected to patterning, and thereby a printed wiring sheet having wiring patterns with a line width of 50 μm and a line spacing of 50 μm was produced.

### Examples 1 to 8 and Comparative Examples 1 to 2

With respect to the combinations of printed wiring sheets and interlayer bonding members shown in Table 3, circuit embedding properties, resistance to soldering heat, long-term heat resistance, and the ratio of change in dimensions were evaluated.

Furthermore, insulating layers obtained by removing wiring layers by etching from the printed wiring sheets shown in Table 3 were laminated with the interlayer bonding member therebetween, and a laminate was produced by application of heat and pressure at 180° C. and 3 MPa for one hour. The dielectric constant and the dielectric loss tangent of the resulting laminate were measured.

Table 1 shows the components and their mixing ratio with respect to the interlayer bonding member produced in each Synthesis Example. Table 2 shows the measurement results of the melt viscosity and dielectric characteristics of the interlayer bonding member and the dielectric characteristics of the insulating layer of the printed wiring sheet in each Synthesis Example. Table 3 shows the evaluation results of the characteristics of the multilayer printed circuit board produced in each of Examples and Comparative Examples.

TABLE 1

| | Synthesis Examples | | | | | |
|---|---|---|---|---|---|---|
| | 5 | 6 | 7 | 8 | 9 | 10 |
| Polyimide resin component | Synthesis | Synthesis Example 3 | Synthesis Example 3 | Synthesis Example 3 | Synthesis Example 3 | — |
| | Example 3 | | | | | |
| Amount used (g) | 90 | 50 | 50 | 100 | 50 | 0 |
| Epoxy resin component | | | | | | |
| Type | 1032H60 | N660 | YX4000H | — | 1032H60 | YX4000H |
| Epoxy equivalent | 168 | 208 | 194 | — | 168 | 194 |
| Amount used (g) | 7.4 | 31.1 | 32.1 | 0 | 37.0 | 64.2 |
| Number of moles of epoxy | 0.044 | 0.150 | 0.165 | 0 | 0.220 | 0.331 |
| group (mol) | | | | | | |
| Epoxy curing agent | | | | | | |
| component | | | | | | |
| Type | DDS | NC30 | BAPS-M | — | DDS | BAPS-M |
| Active hydrogen equivalent | 62 | 126 | 108 | — | 62 | 108 |
| Amount used (g) | 2.6 | 18.9 | 17.9 | — | 13.0 | 35.8 |
| Number of moles of active | 0.042 | 0.150 | 0.166 | — | 0.210 | 0.331 |
| hydrogen group (mol) | | | | | | |
| Imidazole (IM) | | | | | | |
| Type | — | C11Z-A | C11Z-A | — | — | C11Z-A |
| Amount used (g) | — | 0.2 | 0.2 | — | — | 0.4 |
| Total number of moles of | 0.044 | 0.150 | 0.165 | 0 | 0.220 | 0.331 |
| epoxy group and hydroxyl | | | | | | |
| group generated by ring- | | | | | | |
| opening thereof (mol/100 g) | | | | | | |

Ultem; manufactured by GE Plastics Japan Ltd.
1032H60; polyfunctional epoxy resin, manufactured by Japan Epoxy Resin Co., Ltd.
N660; cresol novolac epoxy resin, manufactured by Dainippon Ink and Chemicals, Inc.
YX4000H; biphenyl epoxy resin, manufactured by Japan Epoxy Resin Co., Ltd.
DDS; 4,4′-diaminodiphenylsulfone, manufactured by Wakayama Seika Kogyo Co., Ltd.
BAPS-M; bis[4-(3-aminophenoxy)phenyl]sulfone, manufactured by Wakayama Seika Kogyo Co., Ltd.
C11Z-A; 2,4-diamino-6-[2′-undecylimidazole-(1′)]-ethyl-s-triazine, manufactured by Shikoku Chemicals Corp.

TABLE 2

| | Synthesis Example | | | | | | | | |
|---|---|---|---|---|---|---|---|---|---|
| | 5 | 6 | 7 | 8 | 9 | 10 | 11 | 12 | 13 |
| Melt | 11,000 | 4,500 | 110 | 153,000 | 5,000 | <10 | — | — | — |
| viscosity | | | | | | | | | |
| (Pa · s) | | | | | | | | | |
| Circuit | ◯ | ◯ | ◯ | X | ◯ | X | — | — | — |
| embedding | | | | | | (flows | | | |
| properties | | | | | | excessively | | | |
| Dielectric | 3.3 | 3.3 | 3.3 | 3.2 | 3.5 | 3.6 | 3.2 | 3.3 | 3.6 |
| constant | | | | | | | | | |
| Dielectric | 0.012 | 0.019 | 0.018 | 0.007 | 0.035 | 0.044 | 0.008 | 0.008 | 0.040 |
| loss tangent | | | | | | | | | |
| Glass | 172 | 175 | 170 | 170 | 171 | 162 | 270 | 190 | — |
| transition | | | | | | | | | |
| temperature | | | | | | | | | |
| (° C.) | | | | | | | | | |

TABLE 3

| | | | Dielectric characteristics | | | | | |
|---|---|---|---|---|---|---|---|---|
| | | Interlayer | of multilayer board | | Circuit | | Long-term heat | Ratio of |
| | Printed wiring | bonding | Dielectric | Dielectric | embedding | Resistance to | resistance retention | change in dimensions |
| | sheet | member | constant | loss tangent | properties | soldering heat | (%) | (%) |
| Example 1 | Synthesis | Synthesis | 3.3 | 0.011 | ◯ | ◯ | 80 | −0.15 |
| | Example 11 | Example 5 | | | | | | |
| Example 2 | Synthesis | Synthesis | 3.3 | 0.017 | ◯ | ◯ | 75 | −0.16 |
| | Example 11 | Example 6 | | | | | | |
| Example 3 | Synthesis | Synthesis | 3.3 | 0.017 | ◯ | ◯ | 73 | −0.18 |
| | Example 11 | Example 7 | | | | | | |
| Example 4 | Synthesis | Synthesis | 3.3 | 0.012 | ◯ | ◯ | 75 | −0.16 |
| | Example 12 | Example 5 | | | | | | |
| Example 5 | Synthesis | Synthesis | 3.3 | 0.017 | ◯ | ◯ | 75 | −0.20 |
| | Example 12 | Example 6 | | | | | | |
| Example 6 | Synthesis | Synthesis | 3.3 | 0.018 | ◯ | ◯ | 70 | −0.20 |
| | Example 12 | Example 7 | | | | | | |
| Example 7 | Synthesis | Synthesis | 3.2 | 0.008 | Δ | ◯ | 75 | −0.16 |
| | Example 12 | Example 8 | | | | | | |
| Example 8 | Synthesis | Synthesis | 3.5 | 0.034 | ◯ | ◯ | 70 | −0.22 |
| | Example 12 | Example 9 | | | | | | |
| Comparative | Synthesis | Synthesis | 3.6 | 0.038 | ◯ | X | 60 | −0.25 |
| Example 1 | Example 13 | Example 5 | | | | | | |
| Comparative | Synthesis | Synthesis | 3.5 | 0.042 | X | X | 40 | −0.35 |
| Example 2 | Example 12 | Example 10 | | | (flows | | | |
| | | | | | excessively) | | | |

As is evident from Comparative Examples 1 and 2, when the insulating layer of the printed wiring sheet and the interlayer bonding member are not selected appropriately, it is not possible to obtain well-balanced characteristics. In contrast, in Examples 1 to 8 in which both the insulating layer and the interlayer bonding member are selected appropriately, excellent characteristics are exhibited.

In one or more embodiments, a total thickness of the non-thermoplastic polyimide film and the adhesive layer in the printed wiring sheet is 30 μm or less, and the thickness of the interlayer bonding member is 50 μm or less.

In one or more embodiments, the multilayer printed circuit board is used at 10 GHz.

In one or more embodiments, the non-thermoplastic polyimide film is a polyimide film produced by reacting an acid dianhydride component containing an acid dianhydride represented by general formula (1) presented above.

In one or more embodiments, the interlayer bonding member includes a thermosetting resin composition including a polyimide resin component (A) containing at least one polyimide resin, an epoxy resin component (B) containing at least one epoxy resin, and an epoxy curing agent component (C) containing at least one epoxy curing agent. In one or more embodiments, at least one polyimide resin contained in the polyimide resin component (A) is produced by reacting an acid dianhydride component containing an acid dianhydride represented by general formula (2) presented above.

In one or more embodiments, the interlayer bonding member has a minimum melt viscosity in a range of 10 Pa·s to 10,000 Pa·s in a semi-cured state and in a temperature range of 60° C. to 200° C., and has a dielectric constant of 3.4 or less and a dielectric loss tangent of 0.025 or less when measured at 12.5 GHz after curing.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

1. A multilayer printed circuit board comprising:
at least two printed wiring sheets laminated with an interlayer bonding member therebetween, wherein at least one of the at least two printed wiring sheets comprises,
a non-thermoplastic polyimide film,
an adhesive layer containing a thermoplastic polyimide disposed on at least one surface of the non-thermoplastic polyimide film, and
a metal wiring layer disposed on the adhesive layer;
wherein the interlayer bonding member contains a thermoplastic polyimide.

2. The multilayer printed circuit board according to claim 1, wherein the total thickness of the non-thermoplastic polyimide film and the adhesive layer in the printed wiring sheet is 30 μm or less, and the thickness of the interlayer bonding member is 50 μm or less.

3. The multilayer printed circuit board according to claim 1, wherein the multilayer printed circuit board is used at 10 GHz.

4. The multilayer printed circuit board according to claim 2, wherein the multilayer printed circuit board is used at 10 GHz.

5. The multilayer printed circuit board according to claim 1, wherein the non-thermoplastic polyimide film is a polyimide film produced by reacting an acid dianhydride component containing an acid dianhydride represented by general formula (1): 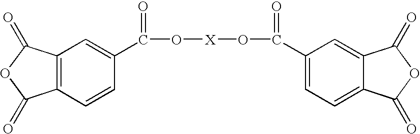
(wherein X represents a divalent organic group containing an aromatic ring) in an amount of 40 mole percent or more of the total acid dianhydride component with an aromatic diamine.

6. The multilayer printed circuit board according to claim 2, wherein the non-thermoplastic polyimide film is a polyimide film produced by reacting an acid dianhydride component containing an acid dianhydride represented by general formula (1): 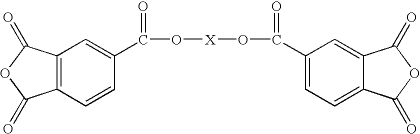
(wherein X represents a divalent organic group containing an aromatic ring) in an amount of 40 mole percent or more of the total acid dianhydride component with an aromatic diamine.

7. The multilayer printed circuit board according to claim 3, wherein the non-thermoplastic polyimide film is a polyimide film produced by reacting an acid dianhydride component containing an acid dianhydride represented by general formula (1): 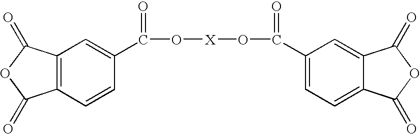
(wherein X represents a divalent organic group containing an aromatic ring) in an amount of 40 mole percent or more of the total acid dianhydride component with an aromatic diamine.

8. The multilayer printed circuit board according to claim 4, wherein the non-thermoplastic polyimide film is a polyimide film produced by reacting an acid dianhydride component containing an acid dianhydride represented by general formula (1): 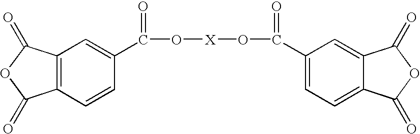
(wherein X represents a divalent organic group containing an aromatic ring) in an amount of 40 mole percent or more of the total acid dianhydride component with an aromatic diamine.

9. (canceled)

10. The multilayer printed circuit board according to claim 1, wherein the interlayer bonding member comprises a thermosetting resin composition including a polyimide resin component (A) containing at least one polyimide resin, an epoxy resin component (B) containing at least one epoxy resin, and an epoxy curing agent component (C) containing at least one epoxy curing agent.

11. The multilayer printed circuit board according to claim 10, wherein at least one polyimide resin contained in the polyimide resin component (A) is produced by reacting an acid dianhydride component containing an acid dianhydride represented by general formula (2): 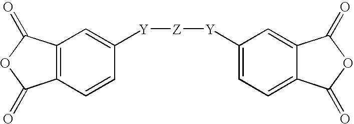
(wherein Y represents —O— or —C(═O)O— and Z represents a divalent organic group) in an amount of 50 mole percent or more with an aromatic diamine component.

12. The multilayer printed circuit board according to claim 1, wherein the interlayer bonding member has a minimum melt viscosity in a range of 10 Pa·s to 10,000 Pa·s in a semi-cured state and in a temperature range of 60° C. to 200° C., and has a dielectric constant of 3.4 or less and a dielectric loss tangent of 0.025 or less when measured at 12.5 GHz after curing.

13. The multilayer printed circuit board according to claim 12, wherein the total thickness of the non-thermoplastic polyimide film and the adhesive layer in the printed wiring sheet is 30 μm or less, and the thickness of the interlayer bonding member is 50 μm or less.

14. The multilayer printed circuit board according to claim 12, wherein the multilayer printed circuit board is used at 10 GHz.

15. The multilayer printed circuit board according to claim 13, wherein the multilayer printed circuit board is used at 10 GHz.

16. The multilayer printed circuit board according to claim 12, wherein the interlayer bonding member comprises a thermosetting resin composition including a polyimide resin component (A) containing at least one polyimide resin, an epoxy resin component (B) containing at least one epoxy resin, and an epoxy curing agent component (C) containing at least one epoxy curing agent.

17. A multilayer printed circuit board comprising at least two printed wiring sheets laminated with an interlayer bonding member therebetween, wherein the printed wiring sheets each include a non-thermoplastic polyimide film, an adhesive layer containing a thermoplastic polyimide disposed on at least one surface of the non-thermoplastic polyimide film, and a metal wiring layer disposed on the adhesive layer, and the interlayer bonding member contains a thermoplastic polyimide.
